(19) United States
(12) Patent Application Publication
(10) Pub. No.: US 2013/0088498 A1
(43) Pub. Date: Apr. 11, 2013

(54) ELECTROMECHANICAL SYSTEMS DEVICE WITH NON-UNIFORM GAP UNDER MOVABLE ELEMENT

(71) Applicants: Yi Tao, San Jose, CA (US); Kostadin Djordjev, San Jose, CA (US); Fan Zhong, Fremont, CA (US)

(72) Inventors: Yi Tao, San Jose, CA (US); Kostadin Djordjev, San Jose, CA (US); Fan Zhong, Fremont, CA (US)

(73) Assignee: QUALCOMM MEMS Technologies, Inc., San Diego, CA (US)

(21) Appl. No.: 13/269,285

(22) Filed: Oct. 7, 2011

(51) Int. Cl. G06T 1/00; G02B 26/00; H01L 21/30

(52) U.S. Cl. 345/501; 438/761; 359/290; 257/E21.211

(57) ABSTRACT

Systems, methods and apparatus are provided for electromechanical systems devices having a non-uniform gap under a mechanical layer. An electromechanical systems device includes a movable element supported at its edges over a substrate by at least two support structures. The movable element can be spaced from the substrate by a gap having two or more different heights in two or more corresponding distinct regions. The gap has a first height in a first region below the gap, such as an active area of the device, and a second height in a second region adjacent the support structure. In an interferometric modulator implementation, the second region can be encompasses within an anchor region with a black mask.

This disclosure relates to electromechanical systems devices and methods for fabricating the same.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Electromechanical systems can include electromechanical systems devices with a gap under a mechanical layer. Different electromechanical systems devices within a system can have different gap heights. For instance, an interferometic modulator configured to represent a blue subpixel can have a gap in an active region with a greater vertical height than a gap in an interferometic modulator configured to represent a green subpixel. The mirror launch effect after removing sacrificial material can be different among different electromechanical systems devices with different gap heights. To actuate devices with different gap heights using the substantially the same voltage, electromechanical systems devices can have mechanical layers with different stiffness, for example, by using different mechanical layer thicknesses. However, these differences can create additional challenges in the design, manufacturing, and/or operation of the electromechanical systems devices.

### SUMMARY

The systems, methods and devices of the disclosure each have several innovative aspects, no single one of which is solely responsible for the desirable attributes disclosed herein.

One innovative aspect of the subject matter described in this disclosure can be implemented in an apparatus that includes a substrate and an electromechanical systems device. The electromechanical systems device includes a plurality of support structures positioned over the substrate and a movable element supported at its edges over the substrate between at least two of the support structures. The movable element is spaced from the substrate by a gap having two or more different heights in each of two or more corresponding distinct regions. The gap has a first height in a first region, and a second height in a second region adjacent one of the at least two support structures.

The electromechanical systems device can include a black mask in which the first region includes an optically active region and the second region is within a footprint of the black mask. The difference between the first height and the second height can be such that the second region would interferometrically reflect a different color than the first region if not masked by the black mask.

The apparatus can include an other electromechanical systems device that can include: an other movable element supported at its edges over the substrate between one of the at least two support structures and one or more other support structures, the movable element spaced from the substrate by an other gap having two or more different heights in two or more corresponding distinct regions; and an other active region over which the other movable element is configured to move between a relaxed position and an actuated position. In the other electromechanical systems device, the other gap can have a third height in an optically active region and a fourth height in a fourth region adjacent a support structure. The first height can differ from the third height by at least about 50 nm.

Another innovative aspect of the subject matter described in this disclosure can be implemented in a method of forming one or more electromechanical systems devices. The method includes forming sacrificial material having a first thickness over a first region of an electromechanical systems device and having a second thickness over a second region of the electromechanical systems device, in which the first thickness differs from the second thickness. The method also includes forming a mechanical layer over the sacrificial material over first region of the electromechanical systems device and the second region of the electromechanical systems device, in which edges of the mechanical layer are formed over at least two support structures.

The first region of the electromechanical systems device can include an active region, and the second region of the electromechanical systems device can be included within an anchor region adjacent at least one of the support structures. Alternatively or additionally, the first thickness and the second thickness can differ by at least about 40 nm.

The method can also include removing the sacrificial material to form a gap under the mechanical layer. The gap can have a first height and a second height that is different from the first height, in which the first height corresponds to the first region and the second height corresponds to the second region. Alternatively or additionally, the method can include forming sacrificial material having a third thickness over a third region of an other electromechanical systems device with a mask used for forming the sacrificial material over the second region, and having a fourth thickness over a fourth region of the other electromechanical systems device with a mask used for forming sacrificial material over the first region. The third thickness can substantially equal the second thickness and the fourth thickness can substantially equal the first thickness. An other mechanical layer over sacrificial material in the third region of the other electromechanical systems device and in the fourth region of the other electromechanical systems device can also be formed, in which the third region and the first region each include an optically active region for interferometrically reflecting color, and the second region and the fourth region are each included within an anchor region adjacent a support post for the mechanical layer.

Another innovative aspect of the subject matter described in this disclosure can be implemented in an apparatus that includes an electromechanical systems device. The electromechanical systems device includes movable means for defining a collapsible gap over a substrate. The movable means are suspended with two or more different gap heights in two or more corresponding regions. The electromechanical systems device also includes a support structure to suspend the movable means over the substrate.

The apparatus can include an interferometric modulator. The movable means can include a mirror layer configured to reflect light in a first region of the two or more distinct regions. The movable means can be configured to collapse over the gap in two or more stages, in which at least one of the two or more stages the movable means collapses over a second region of the two or more distinct regions prior to collapsing over a first region of the two or more distinct regions. The apparatus can include a substantially transparent substrate to support the electromechanical systems device.

Yet another innovative aspect of the subject matter described in this disclosure can be implemented in an apparatus that includes an optical electromechanical systems device. The optical electromechanical systems device has a substrate, a black mask, a plurality of support structures, and a movable element supported at its edges over the substrate between at least two support structures. The substrate and the movable element define a gap therebetween. The gap has a first height in a first region that includes an active region for reflecting light, and the gap also has a second height in a second region within a footprint of the black mask. The first and second heights are different.

The active region can be configured to interferometrically reflect color. The first and second heights can differ by at least about 50 nm. The gap can contain air. The movable element can be configured to collapse in at least two distinct stages upon application of an actuation voltage, including collapsing over the second region prior to collapsing over the first region.

The apparatus can include an other electromechanically systems device. The electromechanical systems device can corresponds to a first subpixel and the other electromechanical systems device can correspond to a second subpixel configured to interferometrically reflect a different color than the first subpixel in their respective relaxed positions.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 shows an example electromechanical systems device with a non-uniform gap under a mechanical layer according to some implementations.

FIGS. 10A-10E show examples of cross-sectional schematic illustrations of various stages in a method of making interferometric modulator devices according to some implementations.

FIG. 11 shows an example of a flow diagram illustrating a manufacturing process for an electromechanical systems device according to some implementations.

FIGS. 12-16 are simulation results related to different non-uniform gaps under a mechanical layer in some implementations.

FIGS. 17A and 17B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device or apparatus that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., electro-mechanical systems (EMS), MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, and electronic test equipment. Thus, the teachings are not intended to be limited to the implementations depicted solely in the Figures, but instead have wide applicability as will be readily apparent to a person having ordinary skill in the art.

A single electromechanical systems device having a mechanical layer spaced from a substrate by a gap having two or more different heights in two or more corresponding distinct regions is disclosed, along with corresponding methods of forming the same. For example, a single electromechanical systems device can have a gap with a first height in an active region, and a second, different height in an inactive region adjacent a support structure supporting the mechanical layer. In an optical MEMS example, the inactive region can be a black mask region, surrounding and underlying a support post.

Particular implementations of the subject matter described in this disclosure can be implemented to realize one or more of the following potential advantages. By providing different gap heights in different regions of the same device, the behavior of the mechanical region is altered such that different heights can be selected to tune launch effects, actuation voltage, dark state performance, stable travel range of a mechanical layer, or any combination thereof in an electromechanical systems device. Such tuning can adjust mirror launch effects to particular values and/or reduce the difference in thickness for mechanical layers of different active gap heights (e.g., blue, green, and red IMODs), thus simplifying processing. The dark state performance can be tuned and/or optimized independently among pixels with different gap heights. The stable travel range of a mechanical layer can be extended several tens of nanometers, which can be useful in, for example, multi-state/analog IMOD. In some implementations, such tuning can be accomplished without adding an additional mask for manufacturing the electromechanical systems device.

An example of a suitable EMS or MEMS device or apparatus, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, e.g., by changing the position of the reflector.

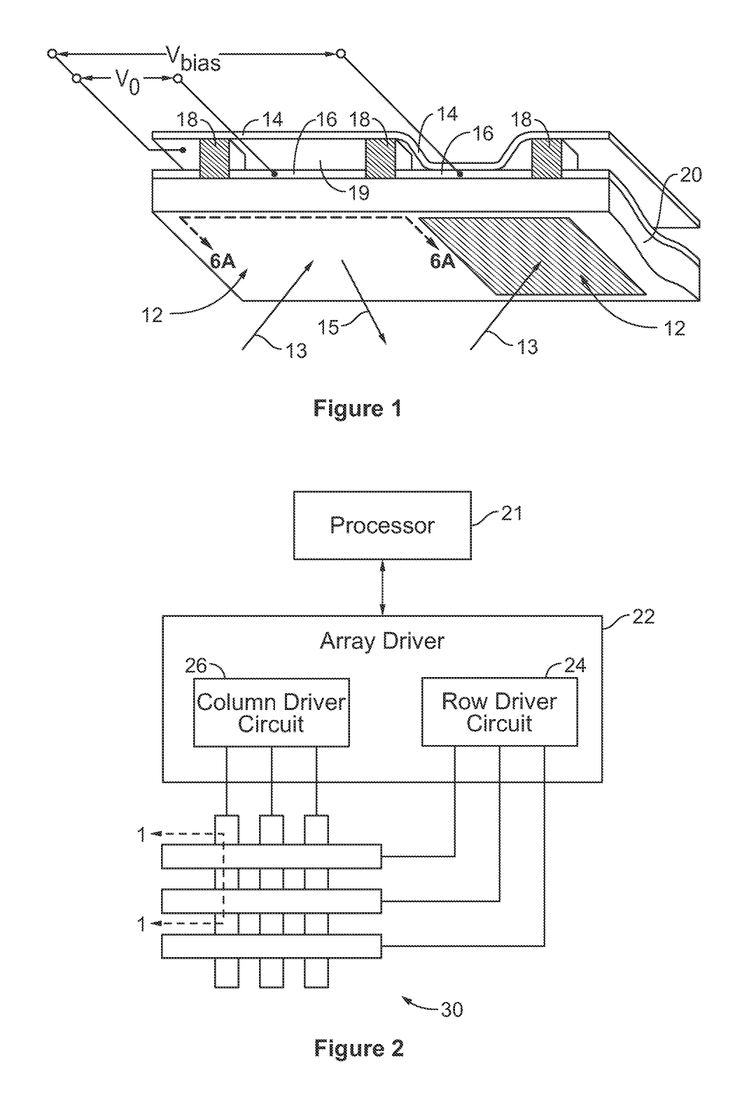

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off') state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, e.g., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent electromechanical systems elements in the form of interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12 on the viewing or substrate side of the device.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be less than approximately 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

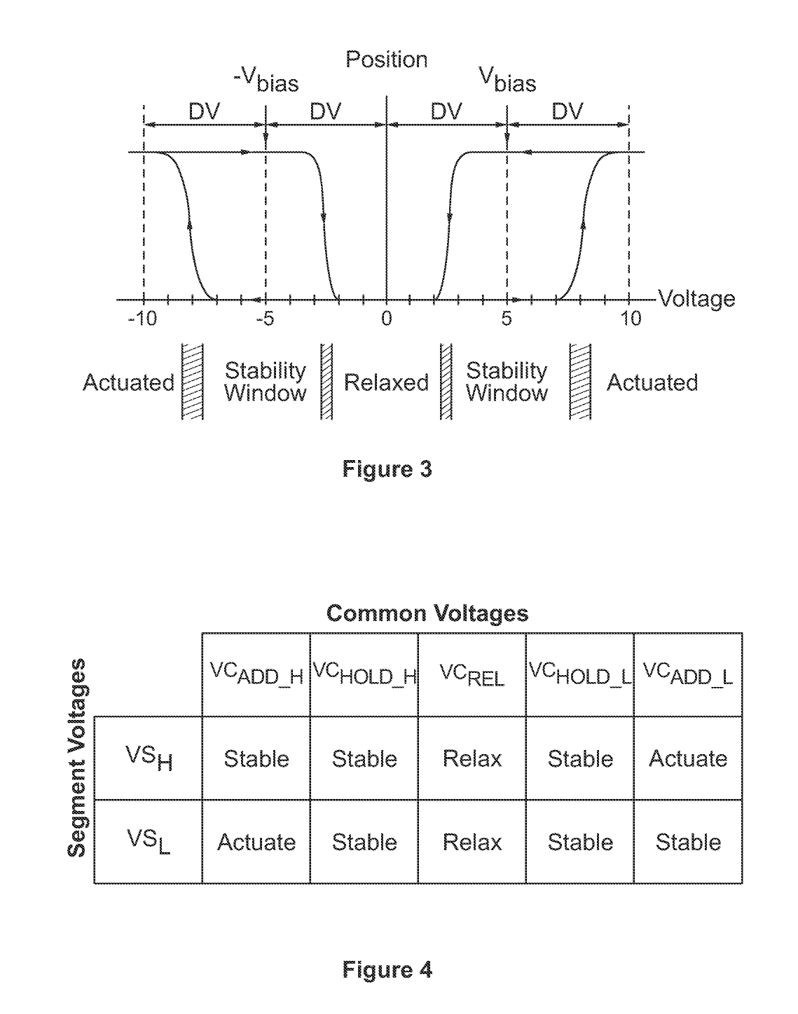

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of the MEMS elements as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the element is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

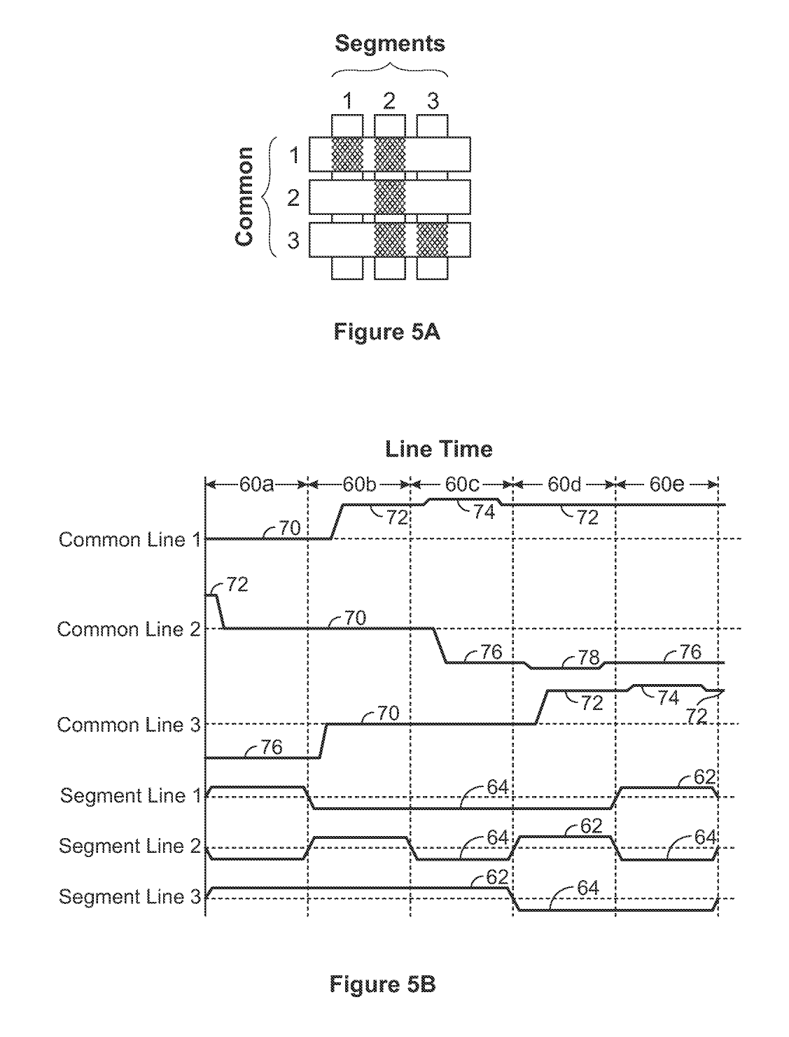

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, in this example the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H}or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation that could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to, e.g., the 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}-relax and VC_{HOLD}_{_{—}}_{L}- stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a characteristic threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

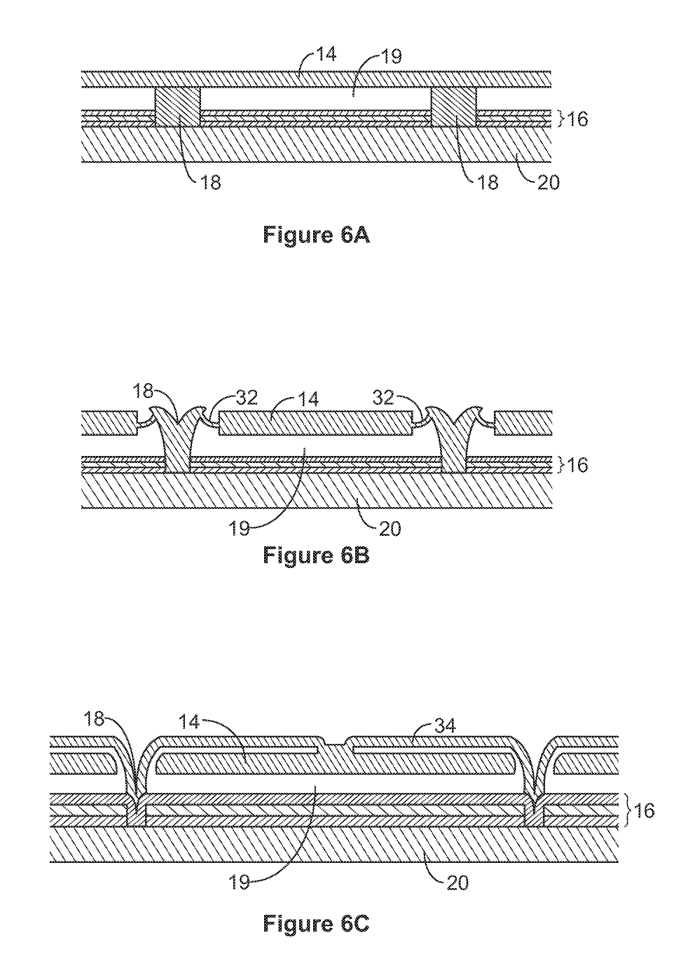

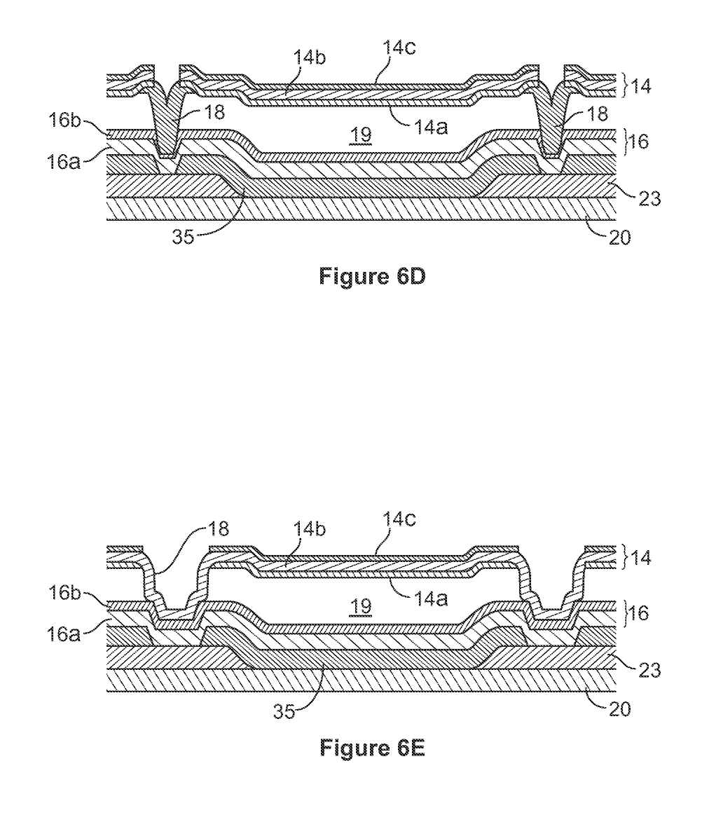

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports such as posts 18 extending orthogonally from the substrate 20. In FIG. 6B, the movable reflective layer 14 of each IMOD is generally square or rectangular in shape and attached to support posts 18 at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as supports or support posts 18. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a and 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under the support posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, tetrafluoromethane (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer or a dielectric layer 35 can serve to generally electrically isolate electrodes or conductor(s) in the optical stack 16 (e.g., the absorber layer 16a) from the conductive layers in the black mask 23.

FIG. 6E shows another example of an IMOD, where the movable reflective layer 14 is self supporting. In contrast with FIG. 6D, the implementation of FIG. 6E does not include separately formed support posts. Instead, the movable reflective layer 14 contacts the underlying optical stack 16 at multiple locations to create integrated supports 18, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a stationary electrode and as a partially reflective layer.

In implementations such as those shown in FIGS. 6A-6E, the IMOD displays function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 that provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

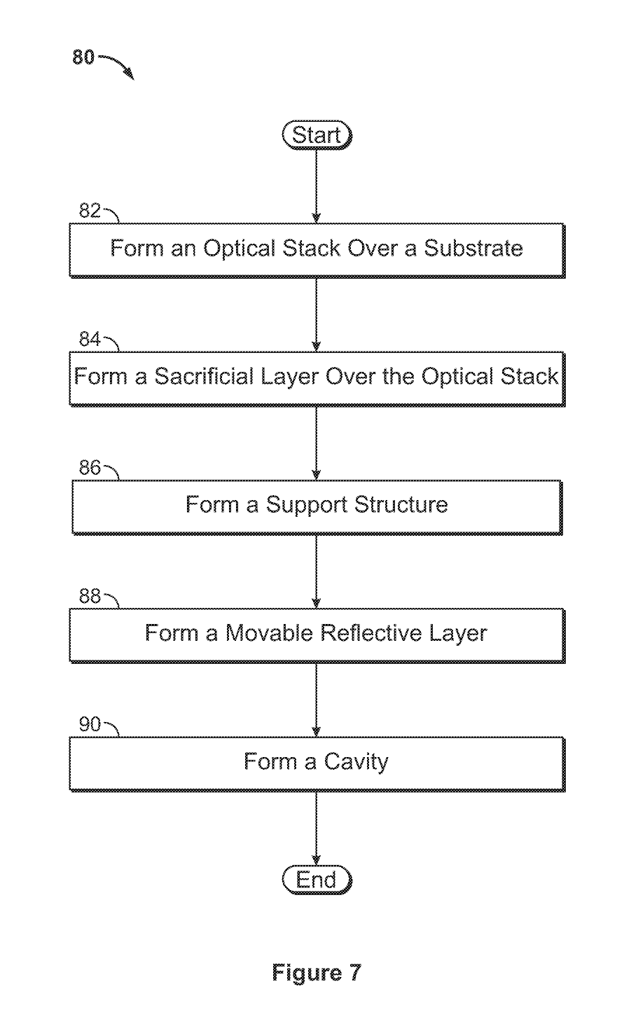

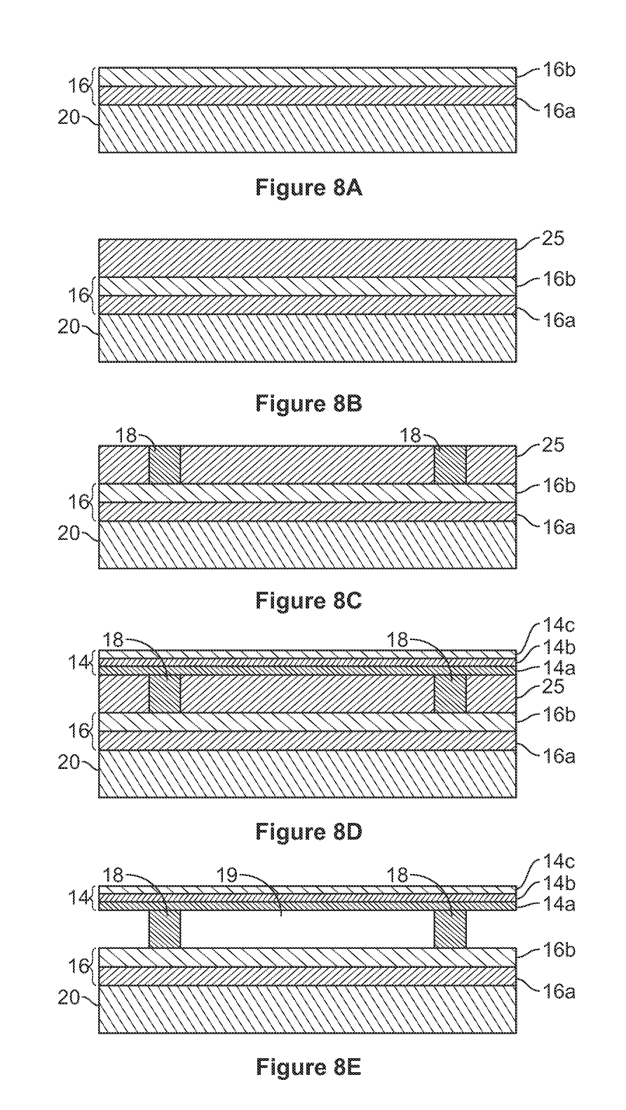

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6A-6E, in addition to other blocks not shown in FIG. 7. With reference to FIGS. 1, 6A-6E, and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators illustrated in FIGS. 1 and 6A-6E. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material, such as molybdenum (Mo) or amorphous silicon (a-Si), in a thickness selected to provide, after subsequent removal, a gap or cavity 19 (see also FIGS. 1, 6A-6E, and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6A, 6D, and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a masking and etching process, but also may be performed by alternative patterning methods.

The process 80 continues at block 88 with the formation of a movable reflective layer or membrane such as the movable reflective layer 14 illustrated in FIGS. 1, 6A-6E, and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a and 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6A-6E, and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂, for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Electromechanical systems devices, such as IMODs, can typically include a substantially uniform gap under the mechanical layer. More specifically, the mechanical layer can typically be spaced apart from a substrate by substantially the same vertical distance over an active region and over an inactive or anchor region. For instance, as shown in FIGS. 1 and 6A-6E, the gap 19 can have a substantially uniform vertical distance separating the movable reflective layer 14 and the optical stack 16 and/or the substrate 20. In some implementations, the gap is between the mechanical layer and a stationary lower electrode, which can include a layer in an optical stack 16.

The gap can refer to a vertical distance separating a mechanical layer from a lower surface, such as a substrate, stationary electrode or optical stack, before sacrificial material below the mechanical layer is removed (i.e., thickness of the sacrificial layer between the mechanical layer and the lower surface) and/or a space between the mechanical layer and the lower surface when the mechanical layer is biased to display a particular color in the open state. The mechanical layer can also serve as and/or include a movable electrode, for example, a movable reflective layer 14 as shown in FIGS. 6A, 6B, 6D, or 6E. Thus, the gap can also refer to vertical distance separating a movable electrode from the lower surface in some implementations. Moreover, even when layers below the mechanical layer include bumps and/or roughness, for example, to reduce stiction without sufficient roughness to affect reflected color of the device were an IMOD, the gap below the mechanical layer can be considered substantially uniform in the context of this disclosure. In an electromechanical systems device in which sacrificial material has been removed, the gaps described herein correspond to a state where the mechanical layer is spaced apart from the lower surface, rather than a state in which the mechanical layer is collapsed and touching the lower surface.

Electromechanical systems can include individual devices with different gaps under their respective mechanical layers. For example, in IMOD implementations, gaps defined by different vertical distances separating the mechanical layer from a lower surface can be used to create different colors in a pixel through interference of reflected light. For instance, a high gap may be used for a blue subpixel and a low gap may be used for a green subpixel. A high gap subpixel can have a gap of about 0.4 μm, and a low gap subpixel can have a gap of about 0.2 μm. In some implementations, a mid gap may be used for a red subpixel as well. A mid gap subpixel can have a gap of about 0.3 μm. One having ordinary skill in this field will appreciate that different gap sizes will produce different color in an IMOD, and that different display colors schemes can be employed.

It can be desirable to tune the actuation voltage, launch effects, dark state performance, stable travel distance of a mechanical layer, the like, or any combination thereof, of the electromechanical systems devices with different gap heights. However, there are a number of obstacles in tuning these parameters in conventional electromechanical systems devices.

Electromechanical systems devices with different gaps under their respective mechanical layers can include mechanical layers formed with different thicknesses/stiffnesses such that each electromechanical systems device can be actuated between an actuated position and a non-actuated position by applying a similar actuation voltage. For instance, a low gap device can have a mechanical layer that is thicker and has a higher stiffness than a high gap device. However, the thickness can vary substantially between low gap and high gap subpixels, for instance, a thickness of a mechanical layer of a high gap subpixel could be as thin as about 100 nm and a thickness of a mechanical layer for a low gap subpixel can be about 600 nm. In some implementations, stiffness tuning can be accomplished by changing the thickness of a dielectric mechanical layer, such as the support layer 14b of FIG. 6E. While such differences in thickness can help large thickness differences to keep the actuation voltages for all subpixels close together or substantially the same, large thickness differences can cause problems in integration, and it would be beneficial to have a single actuation voltage without large mechanical layer differentials.

Tuning dark state performance of a pixel for better contrast can be accomplished by increasing black mask size and/or increasing mirror launch. A larger black mask size can decrease a fill factor. Alternatively or additionally, a larger mirror launch may not be achieved due to other design constraints. Accordingly, it can be desirable to tune dark state performance through different methods.

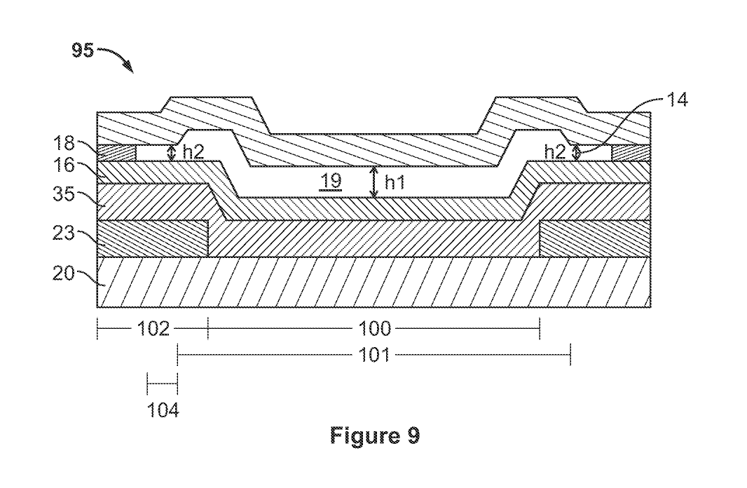

FIG. 9 shows an example electromechanical systems device with a non-uniform gap under a mechanical layer according to some implementations. A single electromechanical systems device 95 with a non-uniform gap 19 under a mechanical layer 14 will be described with reference to FIG. 9. The single electromechanical systems device 95 can be an optical device, such as an IMOD, although the gap size modulation described herein can also be applied to non-optical electromechanical systems devices. The single electromechanical systems device 95 can be included in an array of electromechanical systems devices. In some implementations, the mechanical layer 14 can be actuated between actuated and non-actuated positions by a single stationary electrode, which can include a conductive layer within the optical stack 16.

A first region 101 can be defined as having a vertical height h1 of the gap 19 under the mechanical layer 14. A second region 104 can be defined as having a vertical height h2 of the gap 19 under the same mechanical layer 14. The vertical heights h1 and h2 can be different, for example, as illustrated in FIG. 9. The first region 101 can include an active region 100 in the single electromechanical systems device 95. In some implementations, the first region 101 can further include a portion of an inactive region, which in the illustrated implementation is an anchor region 102.

The anchor region 102 surrounds and underlies a support structure or post 18, such as the support posts 18 of FIGS. 6A-6E. The mechanical layer 14 for the electrochemical systems device 95 can include a movable element supported at its edges over the substrate between at least two of the support structures, such as posts 18, such that the movable element is spaced from the substrate by the gap 19 at two or more different heights h1 and h2 in each of two or more corresponding distinct regions 101 and 104 between the posts 18. In the illustrated IMOD implementation, the anchor region 102 is rendered optically inactive by the underlying black mask structure 23.

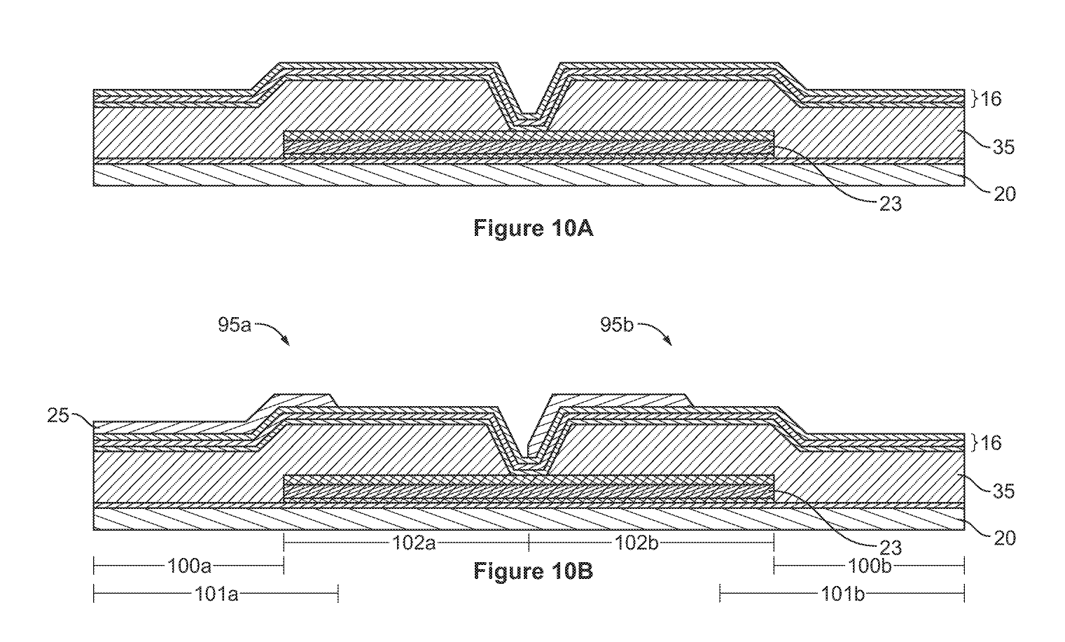

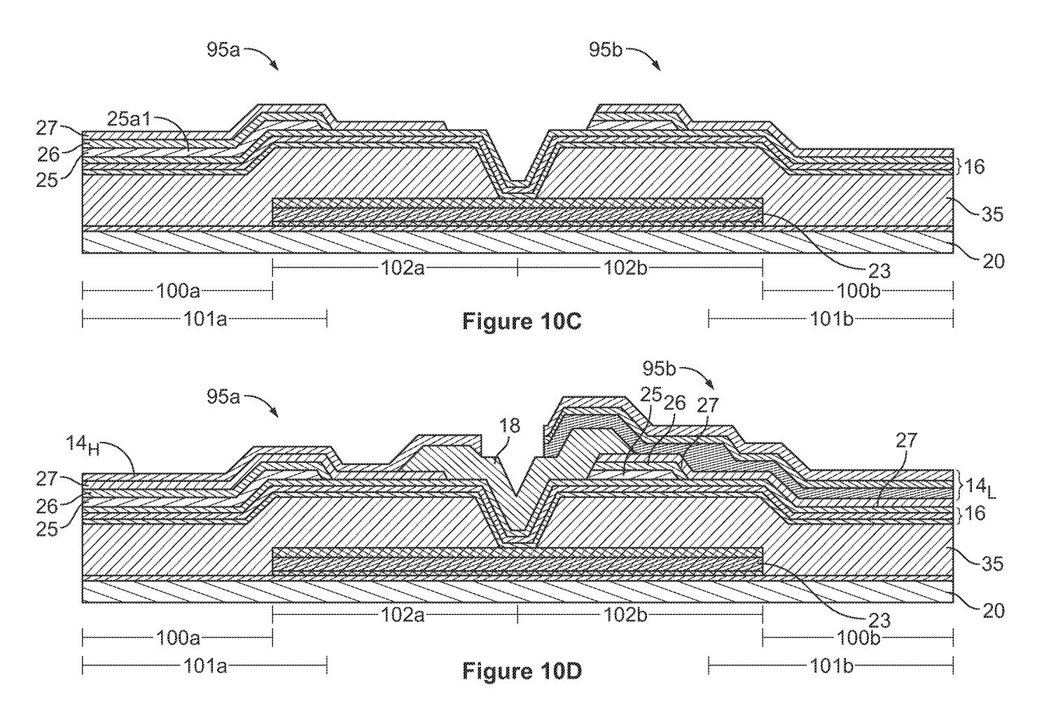

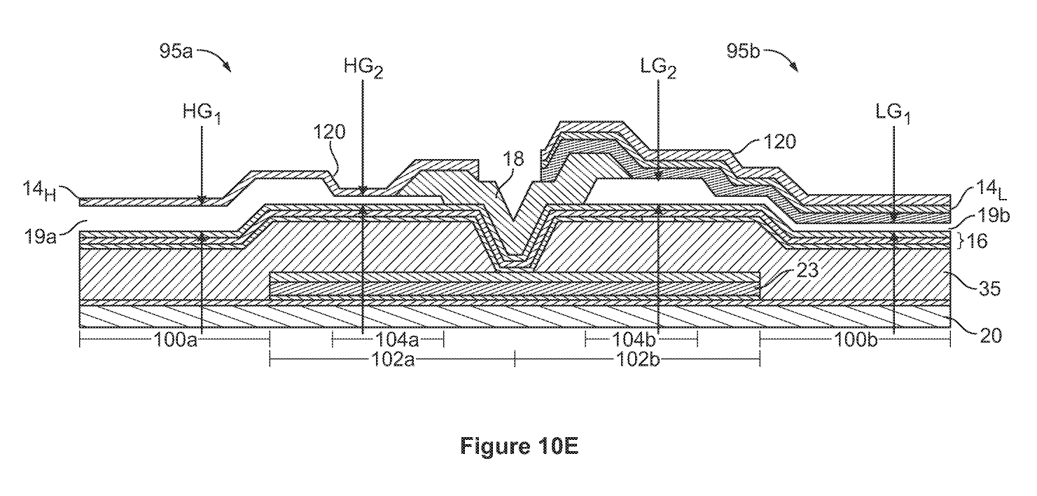

The second region 104 can be included in the anchor region 102 in the single electromechanical systems device 95. Thus, the illustrated non-uniform gap 19 includes two different heights h1 and h2 over two distinct regions, the first region 101 and the second region 104, respectively. In some implementations, the different heights h1 and h2 can differ by at least 25 nm, 50 nm, 100 nm, or more. Thus, the difference between the heights h1 and h2 can be optically significant, such as would affect interferometrically reflected color if the second region was not covered by the black mask 23. For instance, if the second region was not covered by the black mask 23, the second region would interferometrically reflect a different color than the first region. The different heights h1 and h2 can be selected to advantageously tune launch effects, actuation voltage, dark state performance, stable travel distance of the mechanical layer 14, or any combination thereof. More detail will be provided below with reference to FIGS. 10E and 12-16.

The first region 101 can represent a majority of the area below the gap 19. In some implementations, the first region 101 can include an optically active region. The active region 100 can interferometrically reflect light in IMOD implementations. The active region 100 can correspond to a region under the mechanical layer 14 under which there is a portion of the gap 19 but under which there is no black mask structure.

In some implementations, the anchor region 102 can be included in a footprint of a black mask, which can correspond to an area covered by the black mask structure 23. Thus, the second region 104 can be included in a footprint of a black mask. In some implementations, the second region 104 can be adjacent to a support structure, such as a post 18. As illustrated in FIG. 9, the second region 104 can extend from a support structure, such as the post 18, toward an edge of the black mask structure 23 that borders the active region 100. The second region 104 can extend to the edge of the black mask structure 23 that borders the active region 100, or can be recessed within the inactive anchor region 102 as shown.

The different heights h1 and h2 under the mechanical layer 95 can be formed by forming sacrificial material having different thicknesses over the first region 101 and the second region 104, respectively. The thickness of sacrificial material formed over the first region 101 can be selected to interferometrically reflect a color in the active region 100 in an optical implementation. In some implementations, the second region 104 can be overlapped or covered by the black mask structure 23. Accordingly, in some implementations, the thickness of sacrificial material over the second region 104 can be selected so as to improve launch effects, actuation voltage, dark state performance, stable travel range of the mechanical layer, or any combination thereof in combination with the thickness of sacrificial material formed over the first region 101 (including the active region 100) selected to maintain selected optical properties. Thus, two or more sacrificial material thicknesses can be used to underlie the mechanical layer 14 of a single electromechanical systems device 95.

FIGS. 10A-10E show examples of cross-sectional schematic illustrations of various stages in a method of making interferometric modulator devices according to some implementations. While particular structures and processes are described as suitable for an interferometric modulator (IMOD) implementation, it will be understood that for other electromechanical systems implementations (e.g., electromechanical switches, optical filters, accelerometers, etc.), different materials can be used or parts modified, omitted, or added. Additionally, in some interferometric modulator display applications, the drawings may not reflect an accurate scale, for example, the horizontal distance between mechanical layers of adjacent rows of devices may be about 3-10 μm, and the lengths or widths of the gaps 19 for individual electromechanical systems devices can be 10's to 100's of microns in the horizontal direction, and the gap heights in active regions can range from about 100 nm to 500 nm. As another example, the distance between pixels or mechanical layers in adjacent devices can be about 100 μm in certain radio frequency MEMS applications (e.g., switches, switched capacitors, varactors, resonators, etc.) while each mechanical layer can be about 30-50 μm long.

FIG. 10A illustrates cross sections of portions of two IMOD devices. The cross section shown in FIG. 10A includes a black mask structure 23 formed over a portion of a substrate 20. The black mask structure 23 appears dark as viewed through a substrate, such as the substrate 20. The black mask structure 23 can include an interferometric stack that can include one or more of an absorber layer that is deposited on or near the substrate surface, an optical cavity layer, and a reflector layer where this interferometric stack is designed to reflect minimal visible light. A dielectric layer 35 is included over the black mask structure 23 and the substrate 20. Above the dielectric layer 35 is an optical stack 16 that includes a stationary electrode and an absorber layer, which can be the same layer, and a dielectric to prevent shorting between the movable electrode and the stationary electrode during actuation.

There are a number of ways of forming sacrificial material with different thicknesses, which can be independently selected to form some or all of the sacrificial materials shown in FIGS. 10B-10D. For example, although the sacrificial material formed as shown in FIGS. 10B-10D can employ depositions of sacrificial material already used for three active gap sizes for color IMOD devices is described for illustrative purposes, the sacrificial material may be formed a number of different ways. In addition, while the sacrificial material illustrated in FIGS. 10B-10D can be formed by an additive process in which sacrificial material having greater thickness is produced by stacking multiple sacrificial layers, it will be understood that sacrificial material can be independently deposited, masked, and/or etched for each region. Alternatively or additionally, a subtractive process (e.g., a single deposition with 3 masks for separate etching) can be used.

Sacrificial material can be formed over the substrate 20 and the optical stack 16. The sacrificial material includes one or more temporary layers, and the sacrificial material can later be removed to form the gap 19 under the mechanical layer 14 (see FIG. 9). The sacrificial material can include more than one layer, or include a layer of varying thickness, to aid in the formation of a display device having a multitude of resonant optical gaps. For example, in a color IMOD array, multiple different IMODs are each provided with, e.g., one of three different gap sizes, where each gap size corresponds to a different reflected color. The formation of sacrificial material over the substrate 20 and the optical stack 16 can include, for example, deposition of a fluorine-etchable material such as molybdenum (Mo), tungsten (W) or amorphous silicon (Si), in a thickness selected to provide, after subsequent removal, a gap 19 having distinct regions with desired heights. Deposition of sacrificial material over the optical stack 16 can be carried out using deposition techniques such as physical vapor deposition (PVD, e.g., sputtering), plasma-enhanced chemical vapor deposition (PECVD), thermal chemical vapor deposition (thermal CVD), or spin-coating.

Referring to FIG. 10B, a first layer of sacrificial material 25 can be formed over a portion of a first electromechanical systems device 95a and over a portion of a second electromechanical systems device 95b. As illustrated, the first electromechanical systems device 95a and the second electromechanical systems device 95b are adjacent to each other. A portion of the first layer of sacrificial material 25 can be formed over an active region 100a of the first electromechanical systems device. At the same time, another portion sacrificial material 25 can be formed over a portion of an anchor region 102b of the second electromechanical systems device 95b, which coincides with the black mask structure 23. In some implementations, sacrificial material can be formed over both the active region 100a of the first electromechanical systems device 95a and a portion of the anchor region 102b of the second electromechanical systems device 95b using the same deposition and mask. By using the same mask, substantially the same thickness of sacrificial material 25 can be formed over these respective regions. Moreover, using the same mask for forming sacrificial material over an active region of one device and over a portion of an anchor region of an other device can be used to make a non-uniform gap under a mechanical layer without adding an additional mask. According to other implementations, masks designed to pattern other features can be used to form sacrificial material over at least a portion of anchor region of a device to create a non-uniform gap under a mechanical layer. In some other implementations, different masks can be used to form sacrificial material over an active region of one device and at least a portion of an anchor region of another device to form devices with non-uniform gaps under their respective mechanical layers.

Referring to FIG. 10C, sacrificial material can be formed over the first electromechanical systems device 95a and the second electromechanical systems device 95b. The sacrificial material can be formed over all of the active region 100a and all of the active region 100b. In the cross section illustrated in FIG. 10C, the thickness of sacrificial material over the active region 100a of the first electromechanical systems device 95a can be suitable for a high gap subpixel. In addition, the thickness of sacrificial material and over the active region 100b of the second electromechanical systems device 95b can be suitable for a low gap subpixel.

As shown in FIG. 10C, different thicknesses of sacrificial material can be formed over an active region and an anchor region, respectively. In some implementations, sacrificial material having a thickness suitable for an active region of a high gap device can be formed over an anchor region of a low gap device. Alternatively or additionally, sacrificial material having a thickness suitable for an active region of a low gap device can be formed over an anchor region of a high gap device. Forming sacrificial material having a thickness corresponding to an active region of one device in an anchor region of an other device with a different thickness of sacrificial material in the corresponding active region can reduce a number of masks for forming sacrificial material with different thicknesses under a single mechanical layer. Moreover, in some implementations, a mid gap device (not shown) can also be included in an array of electromechanical systems devices. The mid gap device can include sacrificial material having substantially the same thickness in an active region and in an anchor region.

In some implementations, three sacrificial layers are deposited and patterned. A high gap device can have sacrificial material having a thickness in an active region defined by three layers of sacrificial material 25, 26, and 27. A mid gap device can have sacrificial material having a thickness in an active region defined by two layers of sacrificial material 26 and 27. A low gap device can have sacrificial material having a thickness in an active region defined by one layer of sacrificial material 27.

FIG. 10D illustrates providing high gap and low gap mechanical layers 14_{H} and 14_{L}, respectively, over the sacrificial material 25, 26, and 27 formed as shown in the FIGS. 10B and 10C. Although not illustrated in FIG. 10D, a mid gap mechanical layer can also be included in an array of electromechanical systems devices. The mechanical layers 14_{H} and 14_{L} can include any combination of features of the mechanical layers described herein, such as mechanical layers 14 shown in FIGS. 6A-6E and 8D-8E. For example, the mechanical layer 14_{H} and/or 14_{L} may include a reflective sub-layer, a support layer, and/or a conductive layer, for example, as illustrated in the implementations shown in FIGS. 6D and 6E. The mechanical layer 14_{H} and/or 14_{L} can be formed by a variety of techniques, such as plasma-enhanced chemical vapor deposition (PECVD). In some implementations, the thickness of the mechanical layer 14_{H} and/or 14_{L} can be selected to be in the range of about 1000-8000 Å. The low gap mechanical layers 14_{L}can have a greater thickness and corresponding stiffness than the high gap mechanical layer 14_{H}. It will be understood that the mechanical layer 14_{H} and/or 14_{L} can include a variety of layers, depending upon the electromechanical systems device functions. For example, the mechanical layer 14_{H} and/or 14_{L} can be made flexible and conductive to function as the movable electrode, for example, as shown in FIG. 6A, or to support a separate movable electrode, for example, as shown in FIG. 6C.

With continued reference to FIG. 10D, a support structure or post 18 can be provided over the black mask structure 23. The post 18 can provide separation of the mechanical layer 14_{H} and/or 14_{L} from a lower stationary electrode (e.g., part of the optical stack 16 in the illustrated IMOD) in a finished device, for example, when the mechanical layer 14_{H} and/or 14_{L} is in a relaxed position. A movable element, such as the mechanical layer 14_{H} and/or 14_{L}, can be supported at its edges over the substrate 20 between at least two of the support structures. The mechanical layer 14_{H} and/or 14_{L} can be self supporting to form an integrated support rather than the illustrated separately formed post 18. It will be understood that the support structure can include any combination of features of the support structures or posts 18 described with reference to FIGS. 6A-6E.

As illustrated in FIG. 10D, the low gap mechanical layer 14_{L} of the second electromechanical systems device 95b has a greater thickness than the high gap mechanical layer 14_{H} of the first electromechanical systems device 95a. This can, for example, provide the second electromechanical systems device 95b with a stiffer low gap mechanical layer 14_{L} compared to the high gap mechanical layer 14_{H}, allowing a common actuation voltage to be used despite the different gap heights for the two devices 95a and 95b. Different thicknesses can be achieved in a number of different manners, including an additive process similar to that used for achieving different sacrificial material thicknesses in FIGS. 10B-10C.

As shown in FIG. 10E, the sacrificial material 25, 26, and 27 can be removed to form gaps 19a and 19b in active regions 100a and 100b under mechanical layers 14_{H} and 14_{L}, respectively. The first electromechanical systems device 95a can be a high gap device (e.g., a blue IMOD). The gap 19a of the first electromechanical systems device 95a has a first high gap height HG₁ in a first region 101a and a second high gap height HG₂ in a second region 104a. In some implementations, the height HG₁ in the first region 101a can be selected from the range of about 250 nm to 600 nm. The height HG₂ in the second region 104a can be less than the height HG₁ in the first region 101a. For instance, the height HG₂ in the second region 104a can be selected from the range of about 150 nm to about 250 nm in some implementations. The first region 101a can include an optically active region 100a. The second region 104a can be included in an anchor region 102a and/or be adjacent to a support structure 18 configured to support the mechanical layer 14_{H}. The high gap mechanical layer 14_{H} can have a kink 120 where the gap 19a transitions between HG₁ in the first region 101a and HG₂ in the second region 104a.

The second electromechanical systems device 95b can be a low gap device (e.g., a green IMOD). The gap 19b of the second electromechanical systems device 95b has a height LG₁ in a first region 101b and a height LG₂ in a second region 104b. In some implementations, the height LG₁ in the first region 101b can be selected from the range of about 150 nm to 300 nm. The height LG₂ in the second region 104b can be greater than the height LG₁ in the first region 101b. For instance, the height LG₂ in the second region 104b can be selected from the range of about 200 nm to about 600 nm in some implementations. The first region 101b can include an optically active region 100b. The second region 104b can be included in an anchor region 102b and/or be adjacent to a support structure configured to support the mechanical layer 14_{L}. The mechanical layer 14_{L} can have a kink 120 where the gap 19b transitions between LG₁ in the first region 101b and LG₂ in the second region 104b.

In some implementations, the height HG₁ of the gap 19a in the first region 101a of the first electromechanical systems device 95a can be approximately equal to the height LG₂ of the gap 19b in the second region 104b of the second electromechanical systems device 95b. In some implementations, the height LG₁ of the gap 19b in the first region 101b of the second electromechanical systems device 95b can be approximately equal to the height HG₂ of the gap 19a in the second region 104a of the first electromechanical systems device 95a.

In the implementation illustrated in FIG. 10E, the vertical height of a gap under a mechanical layer over an active region is different than the vertical height of the gap under the same mechanical layer over a distinct region included in the non-active or anchor region. Thus, the gap has two distinct heights in two distinct regions of the same electromechanical systems device. For example, as illustrated by the first electromechanical systems device 95a, the vertical height HG₂ of the gap 19a over the second region 104a included in the anchor region 102a can be less than the vertical height HG₁ of gap 19a over the active region 100a. In another example, as illustrated by the second electromechanical systems device 95b, the vertical height LG₂ of the gap 19b over the second region 104b included in the anchor region 102b can be greater than the vertical height LG₁ of the gap 19b over the active region 100b. In these examples, the difference in gap height within a single electromechanical systems device can be optically significant, e.g., in the range of 100's of nanometers.

Although not illustrated, in other implementations, two electromechanical systems devices in the same system can each have non-uniform gaps under their respective mechanical layers with the substantially the same gap height in one distinct region but different gap heights in different regions. For instance, two devices can have substantially the same gap height in their active regions, but have different heights in distinct regions included within their respective anchor regions. As another example, two devices can have substantially the same gap height in a distinct region within the anchor region, but have different heights in their respective active regions. In some implementations, a mid gap subpixel and a low gap subpixel can have substantially the same gap height in a distinct region included within their respective anchor regions. Alternatively or additionally, a mid gap subpixel and a high gap subpixel can have substantially the same gap height in a distinct region included within their respective anchor regions. It will be understood that a low gap subpixel, a mid gap subpixel, and a high gap subpixel will each have different gap heights in their respective active regions.

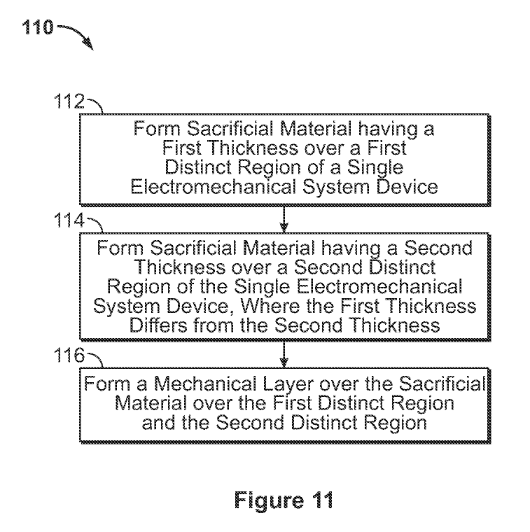

FIG. 11 shows an example of a flow diagram illustrating a manufacturing process 110 for an electromechanical systems device according to some implementations. Sacrificial material is formed over a first distinct region of a single electromechanical systems device at block 112. The sacrificial material formed over the first distinct region can have a first thickness. At block 114, sacrificial material is formed over a second distinct region of the single electromechanical systems device. The sacrificial material formed over the second distinct region can have a second thickness that is different from the first thickness. For example, the first thickness and the second thickness can differ by at least about 25 nm, 40 nm, 50 nm, 60 nm, 80 nm, 100 nm, or more. In some implementations, the first distinct region of the single electromechanical systems device includes an active region and the second distinct region of the single electromechanical systems device is included within an anchor region adjacent a support post for the mechanical layer.

A mechanical layer is formed over the first distinct region and the second distinct region of the single electromechanical systems device at block 116. The mechanical layer is formed when sacrificial material having the first thickness is over the first distinct region and sacrificial material having the second thickness is over the second distinct region. The sacrificial material can later be removed to form a gap under the mechanical layer. The gap can have a first height in the first distinct region that is different from a second height in the second distinct region. The first height and the second height can correspond to the first thickness and the second thickness, respectively.

The process 110 can be applied to forming more than one electromechanical systems devices. In some implementations, sacrificial material is formed over a third distinct region of an other electromechanical systems device. In addition, sacrificial material can be formed over a fourth distinct region of the other electromechanical systems device. Another mechanical layer can be formed over the third distinct region and the fourth distinct region of the other electromechanical systems device. Sacrificial material of a third thickness can be over the third distinct region of the other electromechanical systems device and sacrificial material of a fourth thickness can be over the fourth distinct region of the other electromechanical systems device when the other mechanical layer is formed. The third distinct region of the other electromechanical systems device and the first distinct region of the single electromechanical systems device can each include an optically active region for interferometrically reflecting light of a particular color. The fourth distinct region of the other electromechanical systems device and the second distinct region of the single electromechanical systems device can be included within an anchor region adjacent a support structure, for example, a post, for the mechanical layer.

In the implementation of FIGS. 10A-10E, the four distinct regions can be formed with two masks. Thus, the sacrificial material over the third distinction region can be formed with a mask used for forming the sacrificial material over the second distinct region and the sacrificial material over the fourth distinct region can be formed with a mask used for forming sacrificial material over the first distinct region. However, one having ordinary skill in this field will appreciate that separate depositions and/or separate masks can be used for each distinct region, and that, in other implementations, there may be no relation among the thicknesses of different regions of different devices.

In an IMOD implementation for a color display, the color display can have IMODs with a third color for, e.g., a RGB display. In one implementation, the third gap is also provided with a different gap height in its anchor regions, in order to tune one or more of launch effects, actuation voltage, dark state performance, stable travel range of mechanical layer, or any combination thereof. In another implementation, the third gap size (e.g., mid gap) IMOD has a substantially constant gap size across active and anchor regions.

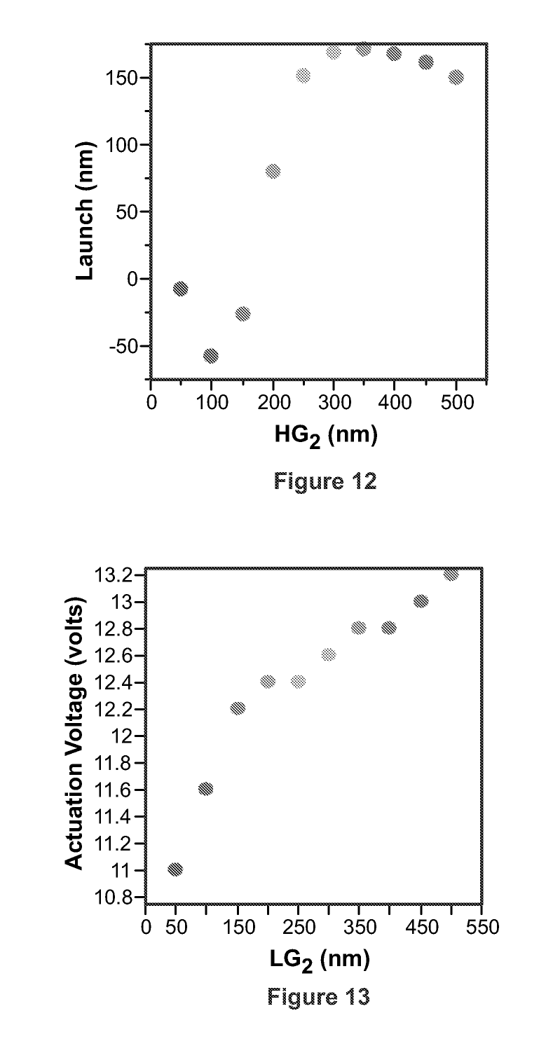

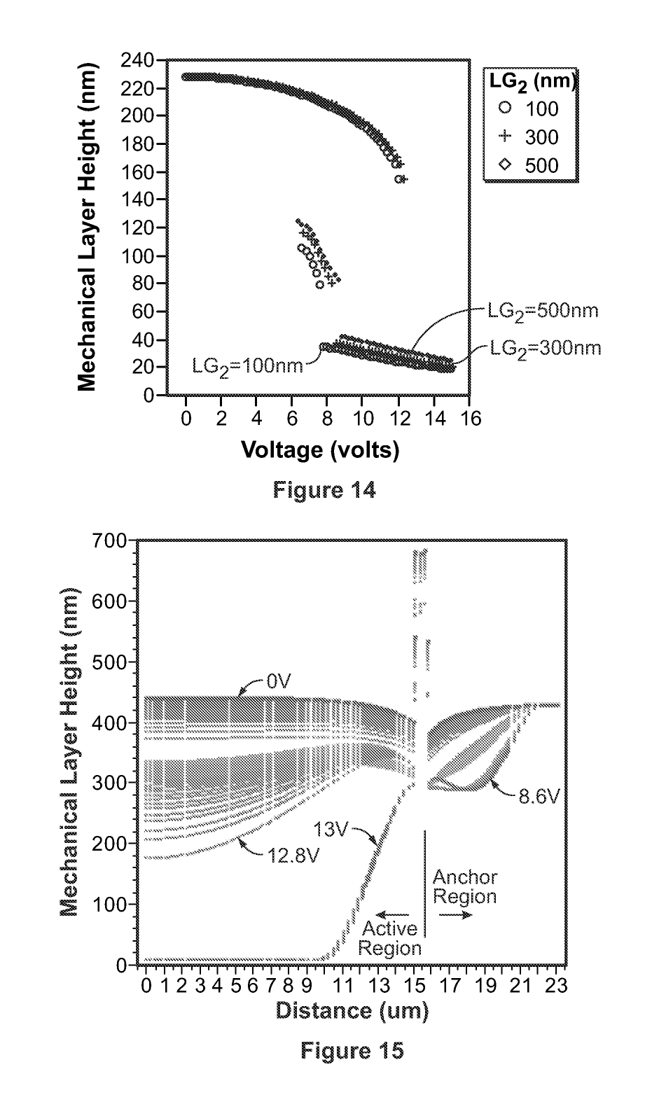

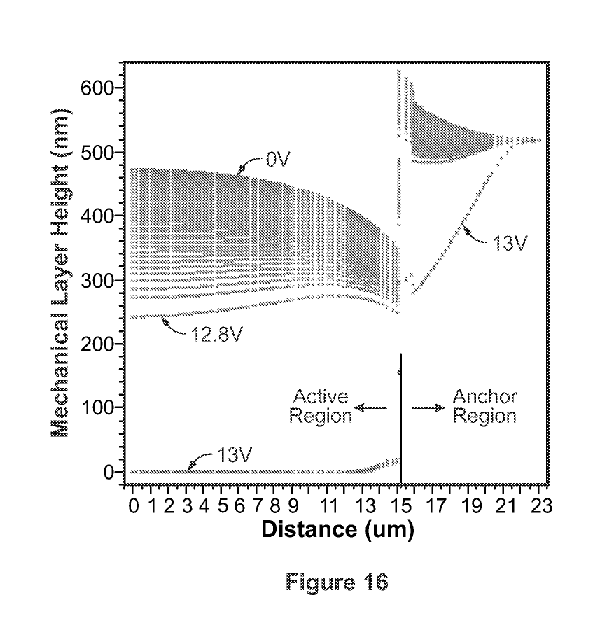

FIGS. 12-16 show simulation results related to different non-uniform gaps under a mechanical layer in some implementations. Non-uniform gaps under a mechanical layer can improve the behavior of mechanical layer operation. For instance, the non-uniform gaps illustrated in FIGS. 9 and 10E, or more generally non-uniform gaps formed by the example process 110 illustrated in FIG. 11, can help normalize the actuation voltage for collapsing devices with different gap heights in their respective active regions, reduce launch effects, improve dark state performance, and increase stable travel range of a mechanical layer, among other things. With such non-uniform gaps, a mechanical layer may collapse in stages. First, a portion of the mechanical layer can collapse over some or all of an anchor region. Second, the mechanical layer can collapse over an active region. This multi-stage actuation can effectively reduce resistance to actuation when the anchor region has a lower gap than the active region, and increase resistance to actuation when the anchor region has a higher gap than the active region. As a result, a smaller differential in mechanical layer stiffness between, e.g., high gap and low gap devices, can be implemented, compared to having uniform gaps for each device, while still normalizing actuation voltage for these different gap devices. Launch effects can also be tuned by adjusting relative heights of the gap in the anchor region as compared to the active region, as described below with respect to FIG. 12. Actuation voltage can also be tuned by selection of anchor gap heights (see FIG. 13, described below). Additionally, because the degree of collapse (which is correlated to the height of the mechanical layer during actuation) can be tuned by selection of the anchor region gap heights (see FIG. 14, described below), IMOD implementations can demonstrate improved dark state performance. The use of distinct gap heights in different regions for a single device also demonstrates distinct actuation stages in the different regions, such that the stable travel range of a mechanical layer can be increased (see FIGS. 15 and 16, described below).

FIG. 12 graphically illustrates a relationship between gap height HG₂ in a majority of the anchor region and launch effects for a high gap subpixel, where the anchor region gap height HG₂ is modulated while maintaining a constant active gap height HG₁. An example of a high gap device is a blue subpixel for a color IMOD display, with an active gap height HG₁ of about 400 nm, although the general relationship demonstrated by FIG. 12 is independent of whether the device is labeled a “high gap” or “low gap” or “mid gap” device. The transition between an anchor region and an active region having different gap heights can form a kink 120. The kink 120 can have a rising shape or a falling shape, depending on a relationship between gap heights corresponding to the anchor region and the active region. For example, as shown in FIG. 10E, the kink 120 in high gap device 95a has a rising shape in transitioning from the anchor gap to the active gap, and the kink 120 in low gap device 95b has a falling shape in transitioning from the anchor gap to the active gap. Due to the tensile residue stress of mechanical layer 14_{L} and/or 14_{H}, the presence of kink structures can create moments to bend the mechanical layer 14_{L} and/or 14_{H} up or down, which can consequently increase or decrease mirror launch. A kink 120 having a rising shape tends to bend the mechanical layer 14_{H} down and consequently reduce mirror launch. In contrast, a kink 120 having a falling shape tends to bend the mechanical layer 14_{L} up and consequently increase mirror launch. As shown in FIG. 12, a smaller anchor region gap height HG₂ relative to active region gap height HG₁ can reduce mirror launch, e.g., when the anchor region gap height HG₂ is within a range from about 100 nm to 300 nm and the active region gap height HG₁ is about 400 nm. Since anchor region gap height HG₂ can be smaller than active region gap height HG₁ in a high gap device, the kink 120 in a high gap device can have a rising shape toward the active gap, which can reduce mirror launch. The kink 120 in low gap device 95b of FIG. 10E has a falling shape toward the active gap since anchor region gap height LG₂ is larger than active region gap height LG₁, which can increase mirror launch. It will be understood that gap height HG₂ does not necessarily span the entire anchor region, and the label “anchor region gap” is used for convenience.

Adjusting thickness of the anchor region gap height can tune pixel actuation voltage and/or dark state performance regardless of the relative gap size of the pixel. Reducing an anchor region gap height for a given active region gap height can decrease pixel actuation voltage and/or improve pixel dark state performance. Conversely, increasing an anchor region gap height can increase pixel actuation voltage and/or make the pixel dark state performance worse, which may be an acceptable trade-off for benefits from tuning other features described herein.

FIG. 13 graphically illustrates a relationship between anchor region gap height LG₂ and actuation voltage. In FIG. 13, simulation results of low gap subpixels with different anchor region gap heights LG₂ with constant mechanical layer thickness and constant gap height LG₁ are shown. An example of a low gap device is a green subpixel for an IMOD display, with an active region gap height LG₁ of about 200 nm, although the general relationship demonstrated by FIG. 13 is independent of whether the device is labeled a “high gap” or “low gap” or “mid gap” device. FIG. 13 demonstrates that the actuation voltage for the low gap device can be tuned to vary within a range of about 2.2 volts by tuning the anchor region gap height LG₂ within a range from about 50 to 500 nm.

FIG. 14 graphically illustrates simulation results of low gap subpixels with different anchor region gap heights (LG₂). In these simulations, the open state active region gap height LG₁ is kept constant at 200 nm. The y-axis represents the position or height of the mechanical layer at different voltages. The upper left curves represent the position of the mechanical layer as the applied voltage is increased, prior to actuation. The lower right curves show the average positions or heights of the mechanical layer after actuation. While the curves are very similar and almost overlap with the different anchor region gaps LG₂, showing that the general hysteresis behavior does not change, the curves shift downward as the anchor region gap height LG₂, decreases. Thus, for a given voltage after actuation, lower anchor region gap heights LG₂ can result in lower mechanical layer positions and thus represent an improved dark state performance. Smaller values of the gap anchor region height LG₂ (for example, 100 nm) produce a smaller average mechanical layer height during a downstate, which indicates improved dark state performance, as compared with use of larger anchor region gap heights LG₂ (for example, 500 nm), which show worse dark state performance.

With electromechanical systems devices including one or more features described herein, such as the devices illustrated in FIGS. 9 and 10E, and an anchor region gap height HG₂ that is relatively smaller than the active region gap height HG₁ of the same device, a portion of the mechanical layer can be actuated over the black mask region at a lower voltage than over the active region.

In FIG. 15, each curve graphically illustrates a profile of a mechanical layer at a particular voltage in a high gap subpixel (such as a subpixel with an active region gap height of about 430 nm) with an anchor region gap height HG₂ of about 150 nm. The mechanical layer is actuated over the anchor region at a voltage of about 8.6 volts, while the mechanical layer is actuated over the active region at about 13 volts. The mechanical layer profile shows two distinct actuation stages, in which the mechanical layer collapses over one distinct region (e.g., an anchor region) prior to collapsing over an other distinct region (e.g., an active region), which can increase the stable travel range of the mechanical layer in the non-actuated state.

The “stable travel range” can refer to a range of a gap 19 below a movable element that can be biased at an open position before the gap 19 collapses. Due to the linear characteristics of the restoration force of the mechanical layer 14 and the nonlinear characteristics of the electrostatic force with respect to the movable element displacement, the movable element can be biased statically at an open position for a portion of a gap 19 beyond which the remainder of the gap 19 may not collapse. Multi-stage collapse can change the restoration force to be nonlinear throughout the whole movable element displacement range. The restoration force can have a smaller ratio to movable element displacement before anchor region actuation (for example, before an actuation voltage of 8.6 V is applied as shown in the graph of FIG. 15) than after anchor region actuation. The nonlinearity of the restoration force before and after anchor region actuation tends to balance the nonlinearity of the electrostatic force with respect to movable element displacement. Thus, the movable element can be biased at a larger gap range than in a single-stage collapse device.

In contrast, FIG. 16 graphically illustrates a mechanical layer profile at different voltages of a high gap subpixel (such as a subpixel having an active region gap height of 430 nm) with an anchor region gap height HG₂ of about 250 nm. With this larger anchor region gap height HG₂, compared to that of FIG. 15, the mechanical layer can be actuated over both the anchor region and the active region at about 13 volts. The stable travel range of the mechanical layer corresponding to the simulation shown in FIG. 16 is about 70 nm less than in the device corresponding to the simulation of FIG. 15. With substantially the same average undriven active region gap height HG₁ of about 430 nm for the simulations corresponding to FIGS. 15 and 16, the center of the movable element can be biased at a minimum active region gap height HG₁ of about 170 nm in FIG. 15, while the movable element center can be biased at a minimum active region gap height of about 240 nm in FIG. 16. The stable travel range of a mechanical layer corresponding to FIG. 15 can be suitable for reflecting first order green, first order red, and second order blue colors; while the stable travel range for a mechanical layer corresponding to FIG. 16 can be suitable for reflecting only first order red and second order blue colors in some implementations.

Multiple stage actuation of the mechanical layer can increase the stable travel range for a subpixel or any other suitable electromechanical systems device. For example, in multi-state/analog IMOD or applications, longer stable travel range can provide larger linear optical and/or electrical output. Moreover, adjusting gap height in the distinct region included within the anchor region can adjust a pivot point representing a point to which the mechanical layer actuates at one stage of the multiple stages. Additionally, tailored different gap heights in the anchor regions can be employed to facilitate normalization of actuation voltages. For example, in a high gap device, when HG₁ is greater than HG₂, resistance to actuation can be reduced relative to when HG₁ and HG₂ are substantially equal. In a low gap device, when LG₁ is less than LG₂, resistance to actuation can be increased relative to when LG₁ and LG₂ are substantially equal. As a result, actuation voltages of a high gap device and a low gap device can be closer to one another. Accordingly, a smaller mechanical layer stiffness differential can achieve normalized actuation voltages of high gap and low gap devices.

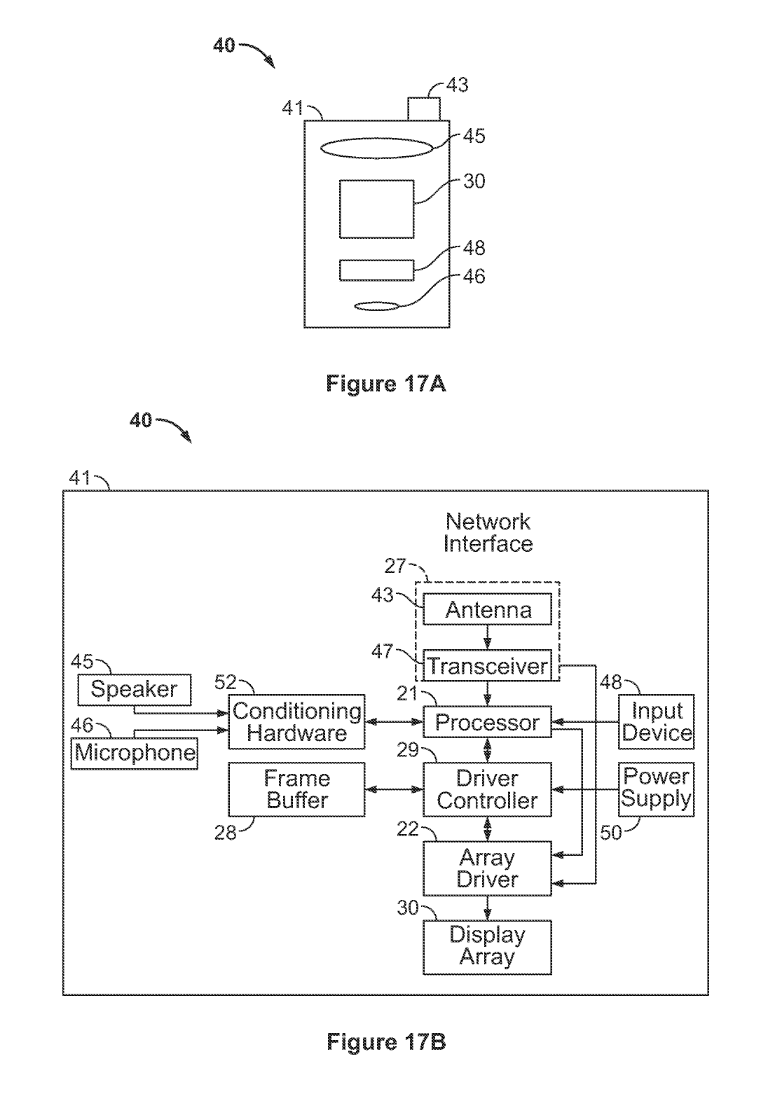

FIGS. 17A and 17B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 17B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), NEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising:
a substrate; and
an electromechanical systems device including:
a plurality of support structures positioned over the substrate; and
a movable element supported at its edges over the substrate between at least two of the support structures, the movable element spaced from the substrate by a gap having two or more different heights in each of two or more corresponding distinct regions;
wherein the gap has a first height in a first region, and a second height in a second region adjacent one of the at least two support structures.

2. The apparatus of claim 1, wherein the electromechanical systems device includes a black mask, and wherein the first region includes an optically active region and the second region is within a footprint of the black mask.

3. The apparatus of claim 1, wherein the electromechanical systems device further includes an active region over which the movable element is configured to move between a relaxed position and an actuated position.

4. The apparatus of claim 3, further including:
an other electromechanical systems device including:
an other movable element supported at its edges over the substrate between one of the at least two support structures and one or more other support structures, the movable element spaced from the substrate by an other gap having two or more different heights in two or more corresponding distinct regions; and
an other active region over which the other movable element is configured to move between a relaxed position and an actuated position;
wherein the other gap has a third height in a third region, the third region including an optically active region, and
wherein the other gap has a fourth height in a fourth region adjacent a support structure.

5. The apparatus of claim 4, wherein the first height differs from the third height by at least about 50 nm.

6. The apparatus of claim 1, wherein the first region represents a majority of area below the gap.

7. The apparatus of claim 1, wherein the electromechanical systems device includes a single stationary electrode to drive the movable element between a relaxed position and an actuated position, wherein the movable element includes a movable electrode.

8. The apparatus of claim 1, wherein the electromechanical systems device is an optical device.

9. The apparatus of claim 8, wherein a difference between the first height and the second height is such that the second region would interferometrically reflect a different color than the first region if not masked by the black mask.

10. The apparatus of claim 8, further including an array of interferometic modulators, wherein the electromechanical systems device is an interferometric modulator in the array.

11. The apparatus of claim 1, wherein at least two of the two or more different heights differ by at least about 25 nm.

12. The apparatus of claim 1, further including:
a display;
a processor that is configured to communicate with the display, the processor being configured to process image data; and
a memory device that is configured to communicate with the processor.

13. The apparatus as recited in claim 12, further including:
a driver circuit configured to send at least one signal to the display.

14. The apparatus as recited in claim 13, further including:
a controller configured to send at least a portion of the image data to the driver circuit.

15. The apparatus as recited in claim 12, further including:
an image source module configured to send the image data to the processor.

16. The apparatus as recited in claim 15, wherein the image source module includes at least one of a receiver, transceiver, and transmitter.

17. The apparatus as recited in claim 12, further including:
an input device configured to receive input data and to communicate the input data to the processor.

18. A method of forming one or more electromechanical systems devices, the method comprising:
forming sacrificial material having a first thickness over a first region of an electromechanical systems device and having a second thickness over a second region of the electromechanical systems device, wherein the first thickness differs from the second thickness; and
forming a mechanical layer over the sacrificial material over first region of the electromechanical systems device and the second region of the electromechanical systems device, wherein edges of the mechanical layer are formed over at least two support structures.

19. The method of claim 18, wherein the first region of the electromechanical systems device includes an active region, and wherein the second region of the electromechanical systems device is included within an anchor region adjacent at least one of the support structures.

20. The method of claim 19, further including:
forming sacrificial material having a third thickness over a third region of an other electromechanical systems device with a mask used for forming the sacrificial material over the second region, and having a fourth thickness over a fourth region of the other electromechanical systems device with a mask used for forming sacrificial material over the first region, wherein the third thickness substantially equals the second thickness and wherein the fourth thickness substantially equals the first thickness; and
forming an other mechanical layer over sacrificial material in the third region of the other electromechanical systems device and in the fourth region of the other electromechanical systems device,
wherein the third region and the first region each include an optically active region for interferometrically reflecting color, and the second region and the fourth region are each included within an anchor region adjacent a support post for the mechanical layer.

21. The method of claim 18, wherein the first thickness and the second thickness differ by at least about 40 nm.

22. The method of claim 18, further including removing the sacrificial material to form a gap under the mechanical layer, the gap having a first height and a second height that is different from the first height, the first height corresponding to the first region, and the second height corresponding to the second region.

23. An apparatus comprising:
an electromechanical systems device including:
movable means for defining a collapsible gap over a substrate, the movable means being suspended with two or more different gap heights in two or more corresponding regions; and
a support structure to suspend the movable means over the substrate.

24. The apparatus of claim 23, wherein the electromechanical systems device includes an interferometric modulator.

25. The apparatus of claim 23, wherein the movable means includes a mirror layer configured to reflect light in a first region of the two or more distinct regions.

26. The apparatus of claim 23, wherein the movable means is configured to collapse over the gap in two or more stages, wherein in at least one of the two or more stages the movable means collapses over a second region of the two or more distinct regions prior to collapsing over a first region of the two or more distinct regions.

27. The apparatus of claim 23, further including a substrate to support the electromechanical systems device, wherein the substrate is substantially transparent.

28. An apparatus comprising:
an optical electromechanical systems device having a substrate, a black mask, a plurality of support structures, and a movable element supported at its edges over the substrate between at least two support structures, the substrate and the movable element defining a gap therebetween, the gap having a first height in a first region that includes an active region for reflecting light, the gap also having a second height in a second region within a footprint of the black mask, wherein the first and second heights are different.

29. The apparatus of claim 28, wherein the active region is configured to interferometrically reflect color.

30. The apparatus of claim 28, wherein the first and second heights differ by at least about 50 nm.

31. The apparatus of claim 28, wherein the gap contains air.

32. The apparatus of claim 28, wherein the movable element is configured to collapse in at least two distinct stages upon application of an actuation voltage, including collapsing over the second region prior to collapsing over the first region.

33. The apparatus of claim 28, further including:
an other electromechanical systems device having an other gap under an other movable element and an other black mask, the other gap having a third height in a third region including an other active region of the other electromechanical systems device, and a fourth height in a fourth region within a footprint of the other black mask,
wherein the second height is less than the first height and the third height is less than the fourth height.

34. The apparatus of claim 33, wherein the electromechanical systems device corresponds to a first subpixel and the other electromechanical systems device corresponds to a second subpixel configured to interferometrically reflect a different color than the first subpixel in their respective relaxed positions.

35. The apparatus of claim 28, wherein the at least two support structures comprise a post, and wherein the post is within the footprint of the black mask.
